(19) United States
(12) Patent Application Publication
(10) Pub. No.: US 2024/0413083 A1
(43) Pub. Date: Dec. 12, 2024

(54) SEMICONDUCTOR DEVICE

(71) Applicant: Murata Manufacturing Co., Ltd., Kyoto-fu (JP)

(72) Inventors: Atsushi KUROKAWA, Nagaokakyo-shi (JP); Hiroshi YAMADA, Nagaokakyo-shi (JP); Akira FUJIHARA, Nagaokakyo-shi (JP)

(73) Assignee: Murata Manufacturing Co., Ltd., Kyoto-fu (JP)

(21) Appl. No.: 18/812,864

(22) Filed: Aug. 22, 2024

Related U.S. Application Data
(63) Continuation of application No. PCT/JP2023/006713, filed on Feb. 24, 2023.

(30) Foreign Application Priority Data
Feb. 28, 2022 (JP) 2022-029467
Nov. 8, 2022 (JP) 2022-178815

(51) Int. Cl. H01L 23/528; H01L 21/768; H01L 23/532; H01L 27/12; H01L 29/45; H01L 29/786

(52) U.S. Cl. CPC H01L 23/5283; H01L 23/53261; H01L 23/53295; H01L 27/1214; H01L 21/76877; H01L 29/45; H01L 29/786

(57) ABSTRACT

A first insulating layer containing a silicon oxide is disposed on a surface of an insulating member. A transistor is disposed over a part of an area of a first insulating layer. A second insulating layer covers the first insulating layer and the transistor. A first wiring is disposed on the second insulating layer. A through-hole extends through the second insulating layer and the first insulating layer from a lower surface of the first wiring to the insulating member. At least a part of an outer edge of the through-hole overlaps the first wiring in a plan view. The first wiring includes a lower layer that is in contact with the second insulating layer, and the lower layer is formed from Ta, W, a Ta compound, or a W compound.

### CROSS-REFERENCE TO RELATED APPLICATIONS

This application claims benefit of priority to International Patent Application No. PCT/JP2023/006713, filed Feb. 24, 2023, and to Japanese Patent Application No. 2022-029467, filed Feb. 28, 2022 and Japanese Patent Application No. 2022-178815, filed Nov. 8, 2022, the entire contents of each are incorporated herein by reference.

### BACKGROUND

### Technical Field

The present disclosure relates to a semiconductor device.

### Background Art

In a wafer process using a silicon on insulator (SOI) substrate, to prevent a support substrate formed from silicon from having a floating voltage, the substrate may have a through-hole extending through a buried oxide layer to a support substrate, and a contact electrode disposed in the through-hole as described, for example, in U.S. Patent Application Publication No. 2004/0217421.

### SUMMARY

In a semiconductor element including an SOI substrate, parasitic capacitance occurs between a support substrate and a semiconductor layer in which components including a transistor are disposed. This parasitic capacitance may lower high-frequency characteristics of the semiconductor element. After a multilayer wiring layer is formed on the semiconductor layer, the support substrate is removed, and thus the parasitic capacitance attributable to the support substrate can be reduced.

When a contact electrode extending through the buried oxide layer is disposed in the SOI substrate, removal of the support substrate exposes the end surface of the contact electrode. During removal of the support substrate by etching, when an etchant arrives at the semiconductor layer or the multilayer wiring layer through the through-hole receiving the contact electrode, the semiconductor element may cause a failure. The present disclosure aims to provide a semiconductor device unlikely to cause a failure attributable to, for example, an etchant entering through a through-hole.

A first aspect of the present disclosure provides a semiconductor device including an insulating member; a first insulating layer containing a silicon oxide and disposed on a surface of the insulating member; a transistor disposed over a part of an area of the first insulating layer; a second insulating layer covering the first insulating layer and the transistor; and a first wiring disposed on the second insulating layer. A through-hole extends through the second insulating layer and the first insulating layer from a lower surface of the first wiring to the insulating member, and at least a part of an outer edge of the through-hole overlaps the first wiring in a plan view. Also, the first wiring includes a lower layer that is in contact with the second insulating layer, and the lower layer is formed from Ta, W, a Ta compound, or a W compound.

Another aspect of the present disclosure provides semiconductor device including an insulating member; a first insulating layer containing a silicon oxide and disposed on a surface of the insulating member; a transistor disposed over a part of an area of the first insulating layer; a second insulating layer covering the first insulating layer and the transistor; a first wiring disposed on the second insulating layer; and a first contact electrode extending through the second insulating layer and the first insulating layer from a lower surface of the first wiring to the insulating member. The first contact electrode includes a first main portion with electroconductivity and a bottom portion disposed nearer the insulating member than the first main portion, and the bottom portion is formed from Ta, W, a Ta compound, or a W compound.

When, for example, an etchant enters through a through-hole, the lower layer of the first wiring functions as a barrier layer to stop further entry of the etchant. The bottom portion of the first contact electrode functions as a barrier layer, and thus stops entry of the etchant into an area where the transistor is disposed. Thus, the semiconductor device can reduce an occurrence of a failure attributable to entry of an etchant.

### BRIEF DESCRIPTION OF THE DRAWINGS

FIG. 1 is a cross-sectional view of a semiconductor device according to a first embodiment;

FIG. 2 is a cross-sectional view of a semiconductor device according to the first embodiment during the manufacturing process;

FIG. 3 is a cross-sectional view of the semiconductor device according to the first embodiment during the manufacturing process;

FIG. 4 is a cross-sectional view of the semiconductor device according to the first embodiment during the manufacturing process;

FIG. 5 is a cross-sectional view of the semiconductor device according to the first embodiment during the manufacturing process;

FIG. 6 is a cross-sectional view of a semiconductor device according to a modification example of the first embodiment;

FIG. 7 is a cross-sectional view of a semiconductor device according to a second embodiment;

FIG. 8A is a cross-sectional view of a semiconductor device according to a third embodiment, illustrating a portion from an insulating member to a third insulating layer, and FIG. 8B is a schematic diagram of a positional relationship between a through-hole, a first contact electrode, and a first wiring in a plan view;

FIG. 9 is a cross-sectional view of a semiconductor device according to a fourth embodiment;

FIG. 10 is a cross-sectional view of a semiconductor device according to a modification example of the fourth embodiment;

FIG. 11 is a cross-sectional view of a semiconductor device according to a fifth embodiment;

FIG. 12 is a cross-sectional view of a semiconductor device according to a sixth embodiment;

FIG. 13A and FIG. 13B are cross-sectional views of the semiconductor device according to the sixth embodiment during the manufacturing process;

FIG. 14 is a cross-sectional view of a semiconductor device according to a seventh embodiment; and

FIG. 15 is a cross-sectional view of a semiconductor device according to an eighth embodiment.

### DETAILED DESCRIPTION

### First Embodiment

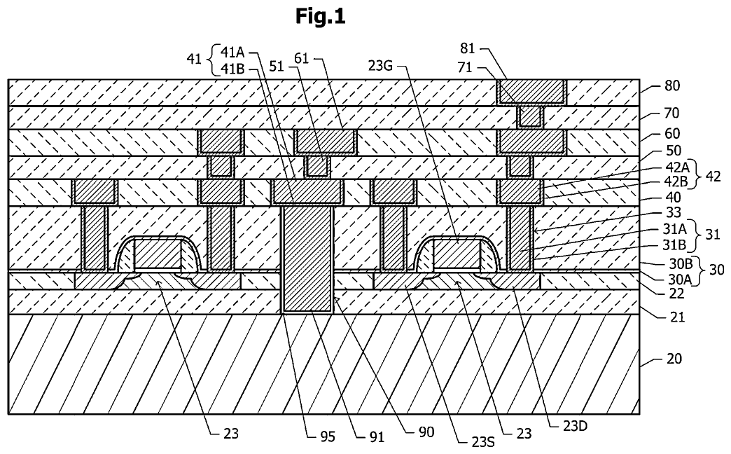

With reference to the drawings in FIG. 1 to FIG. 5, a semiconductor device according to a first embodiment is described.

FIG. 1 is a cross-sectional view of a semiconductor device according to a first embodiment. A first insulating layer 21 containing a silicon oxide is joined to a surface of an insulating member 20. “Containing” here means that the first insulating layer 21 “contains” a silicon oxide “as a main component”. For example, the first insulating layer 21 may be formed from a silicon oxide containing impurities that do not affect its function as the insulating film and its etching characteristics. The insulating member 20 is formed from, for example, an insulating polymer (a polymeric compound). The insulating member 20 is joined to the first insulating layer 21 using, for example, adhesion of the polymer. Alternatively, the insulating member 20 and the first insulating layer 21 may be joined together with an adhesive layer at the interface between the insulating member 20 and the first insulating layer 21. The direction in which the surface of the insulating member 20 joined to the first insulating layer 21 faces is defined as upward. More specifically, the first insulating layer 21 is disposed above the insulating member 20.

Multiple transistors 23 are disposed over a part of an area of the first insulating layer 21. Each of the multiple transistors 23 is, for example, an electric field-effect transistor (FET) including, a source area 23S, a drain area 23D, and a gate electrode 23G. The source area 23S, the drain area 23D, and a channel area between the source area 23S and the drain area 23D are formed in an element forming layer 22 disposed on the first insulating layer 21. An area of the element forming layer 22 where no transistor 23 is disposed serves as an insulating element isolation area.

A second insulating layer 30 is disposed to cover the first insulating layer 21, the element forming layer 22, and the transistors 23. The second insulating layer 30 includes two layers, or a lower insulating layer 30A deposited on a surface of a base in a conformal manner, and an upper insulating layer 30B having a flat upper surface.

A through-hole 90 extends through the second insulating layer 30, the element isolation area of the element forming layer 22, and the first insulating layer 21 from the upper surface of the second insulating layer 30 to the insulating member 20. A first contact electrode 91 is disposed in the through-hole 90. The first contact electrode 91 is formed from, for example, W or a W compound.

An interstice 95 is formed between the side surface of the through-hole 90 and the first contact electrode 91. The lower end of the first contact electrode 91 is located slightly above the lower surface of the first insulating layer 21. Although a gap is formed between the first contact electrode 91 and the insulating member 20 in FIG. 1, the insulating member 20 may be in contact with the lower end of the first contact electrode 91 with flexibility of the insulating member 20.

Through-holes 33 extend through from the upper surface of the second insulating layer 30 to the source areas 23S and the drain areas 23D of the transistors 23. The through-holes 33 are filled with second contact electrodes 31. Each second contact electrode 31 is connected to the source area 23S or the drain area 23D. Although not illustrated in a cross section in FIG. 1, any of the second contact electrodes 31 is also connected to the gate electrode 23G.

Each second contact electrode 31 includes a conductor film 31B that covers the side surface and the bottom surface (an upper surface of the drain area 23D exposed to the through-hole 33) of the corresponding through-hole 33, and a main portion 31A that fills the remaining space. The main portion 31A is formed from, for example, W or a W compound. The conductor film 31B is formed from, for example, Ti or a Ti compound (for example, TiN).

A third insulating layer 40 is disposed on the second insulating layer 30. The third insulating layer 40 has multiple wiring trenches that are filled with a first wiring 41 and multiple second wirings 42. The first wiring 41 is located to cover the through-hole 90 in a plan view, and connected to the first contact electrode 91. The multiple second wirings 42 are connected to the source area 23S and the drain area 23D with the second contact electrodes 31 interposed therebetween. “In a plan view” indicates a view when viewed facing the surface of the insulating member 20 on which the first insulating layer 21 is disposed, and viewed parallel to a direction in which the first insulating layer 21 and the second insulating layer 30 are laminated. A structure “where the first wiring 41 covers the through-hole 90 in a plan view” includes a structure where the outer edge of the first wiring 41 is disposed outside the outer edge of the through-hole 90 in a plan view, and a structure where the outer edge of the first wiring 41 agrees with the outer edge of the through-hole 90 in a plan view.

The first wiring 41 includes a lower layer 41B that covers the side surface and the bottom surface of the wiring trench, and a main portion 41A disposed on the lower layer 41B to fill the remaining area in the wiring trench. In the first wiring 41, particularly, the lower layer 41B is located to cover the through-hole 90 in a plan view. Similarly, each second wiring 42 includes a lower layer 42B and a main portion 42A. The lower layer 41B of the first wiring 41 and the lower layer 42B of each second wiring 42 are formed from Ta, W, a Ta compound (such as TaN or TaSi), or a W compound (such as WN or WSi). The main portion 41A of the first wiring 41 and the main portion 42A of each second wiring 42 are formed from Cu, a Cu alloy, or Al.

A multilayer wiring layer is disposed on the third insulating layer 40, the first wiring 41, and the second wirings 42. The multilayer wiring layer includes a fourth insulating layer 50, a fifth insulating layer 60, a sixth insulating layer 70, and a seventh insulating layer 80, which are sequentially laminated from below. The fourth insulating layer 50 has multiple via holes, and these via holes are filled with via conductors 51. The fifth insulating layer 60 has multiple wiring trenches, and these wiring trenches are filled with third wirings 61. The sixth insulating layer 70 has multiple via holes, and these via holes are filled with via conductors 71. The seventh insulating layer 80 has multiple wiring trenches, and these wiring trenches are filled with fourth wirings 81. As in the case of the first wiring 41 and the second wirings 42, each of the via conductors 51 and 71, the third wirings 61, and the fourth wirings 81 includes a main portion and a lower layer.

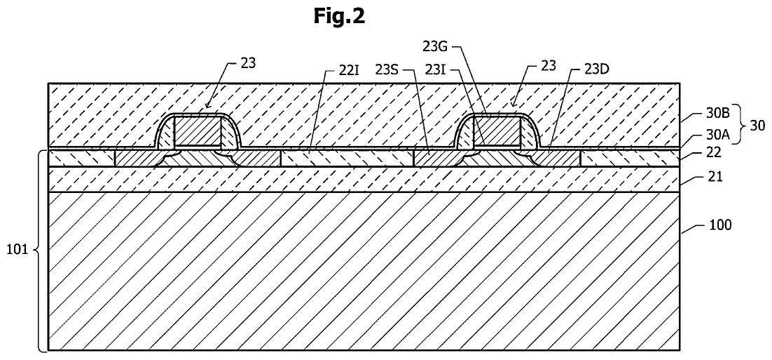

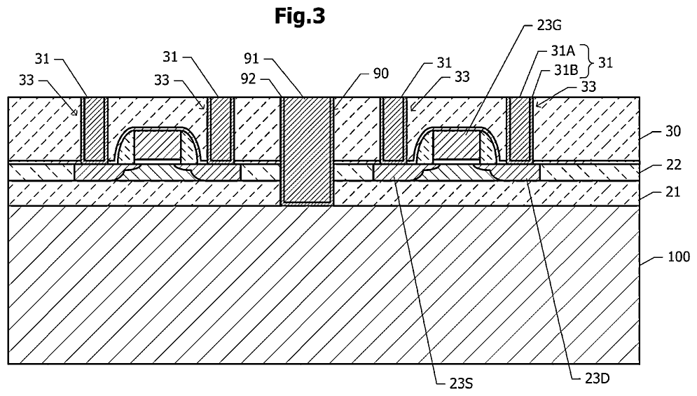

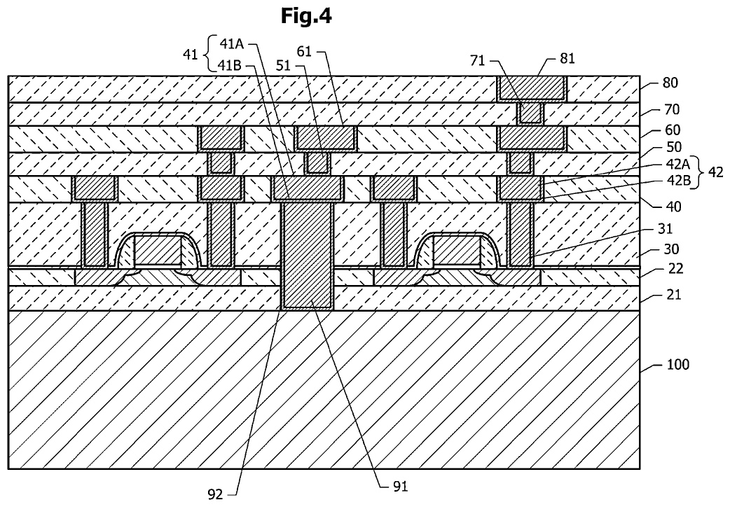

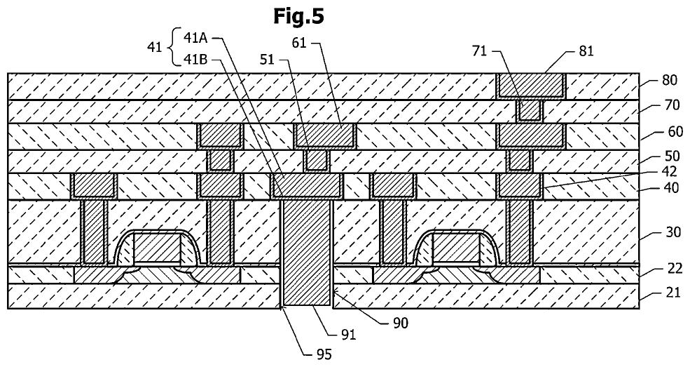

With reference to the drawings in FIG. 2 to FIG. 5, a method for manufacturing the semiconductor device according to the first embodiment is described now. FIG. 2, FIG. 3, FIG. 4, and FIG. 5 are cross-sectional views of the semiconductor device according to the first embodiment during the manufacturing process.

As illustrated in FIG. 2, an SOI substrate 101 is prepared. The SOI substrate 101 includes a temporary support substrate 100 formed from single crystal silicon, the first insulating layer 21 formed from a silicon oxide, and the element forming layer 22 formed from single crystal silicon. The first insulating layer 21 may be referred to as a buried oxide layer (BOX layer). The element forming layer 22 have insulating element isolation areas 221, and multiple active regions defined by the element isolation areas. The element isolation areas 221 are formed by, for example, shallow trench isolation (STI).

The multiple transistors 23 are formed by a normal wafer process within and over the multiple active regions of the element forming layer 22. Each of the transistors 23 is a FET including the source area 23S, the drain area 23D, a gate insulating film 23I, and the gate electrode 23G. A silicide film (not illustrated) formed from, for example, Ni or Co is disposed on the surfaces of the source area 23S, the drain area 23D, and the gate electrode 23G.

The second insulating layer 30 is disposed to cover the element forming layer 22 and the transistors 23. The second insulating layer 30 includes the lower insulating layer 30A covering the surface of the base in a conformal manner, and the upper insulating layer 30B deposited on the lower insulating layer 30A. The lower insulating layer 30A is formed from an inorganic insulating material such as a silicon oxide or a silicon nitride. The upper insulating layer 30B is formed from an inorganic or organic material with a low dielectric constant (a low-k material). The upper insulating layer 30B is formed by, for example, spin-on-glass (SOG), and has a substantially flat upper surface.

As illustrated in FIG. 3, the through-hole 90 that extends through the second insulating layer 30, the element isolation area of the element forming layer 22, and the first insulating layer 21 to the temporary support substrate 100, and the multiple through-holes 33 that extend through the second insulating layer 30 to the source areas 23S and the drain areas 23D of the transistors 23 are formed. The first contact electrode 91 is formed in the through-hole 90, and the second contact electrodes 31 are formed in the multiple through-holes 33. The first contact electrode 91 and the second contact electrodes 31 are formed by, for example, damascening.

The side surface and the bottom surface of each through-hole 33 are covered with the conductor film 31B. The remaining space of each through-hole 33 is filled with the main portion 31A. Similarly, the side surface and the bottom surface of the through-hole 90 are covered with an electroconductive member 92. The remaining space of the through-hole 90 is filled with the first contact electrode 91. Each of the multiple second contact electrodes 31 is electrically connected to the source area 23S or the drain area 23D. The first contact electrode 91 is electrically connected to the temporary support substrate 100.

The main portions 31A of the second contact electrodes 31 and the first contact electrode 91 are formed from, for example, W or a W compound (such as WN). The electroconductive member 92 in the through-hole 90 and the conductor films 31B of the second contact electrodes 31 are formed from, for example, Ti or TIN. The electroconductive member 92 and the conductor films 31B may have a laminate structure including a Ti film and a TiN film.

As illustrated in FIG. 4, a multilayer wiring layer from a first wiring layer in which the first wiring 41 and the second wirings 42 are disposed to a third wiring layer in which the fourth wirings 81 are disposed is disposed on the second insulating layer 30. A multilayer wiring layer including four or more layers may be formed as needed. The insulating layers in the multilayer wiring layer are formed from, for example, a silicon oxide, a silicon nitride, a silicon oxynitride, or a low-k material. The multilayer wiring layer is formed by damascening or dual damascening. Instead, the multilayer wiring layer may be formed by a subtractive process.

The first wiring 41 includes the lower layer 41B covering the side surface and the bottom surface of the wiring trench, and the main portion 41A that fills the wiring trench. Each second wiring 42 includes the lower layer 42B covering the side surface and the bottom surface of the wiring trench, and the main portion 42A that fills the wiring trench. The lower layers 41B and 42B are formed from, for example, Ta, W, a Ta compound (such as TaN or TaSi), or a W compound (such as WN and WSi). The lower layers 41B and 42B may have a laminate structure including films formed from these materials. The main portions 41A and 42A may be formed from, for example, Cu, Al, or a Cu alloy.

As illustrated in FIG. 5, the temporary support substrate 100 (FIG. 4) is removed by etching using an acid or alkaline etchant. During etching of the temporary support substrate 100, an adhesive tape, a protective plate, or another member is bonded to the upper surface of the multilayer wiring layer. During this etching, the electroconductive member 92 formed in the through-hole 90 is also etched to form the interstice 95 between the side surface of the through-hole 90 and the first contact electrode 91. The first contact electrode 91 is scarcely etched. The lower end of the first contact electrode 91 is located at a position higher by the thickness of the electroconductive member 92 (FIG. 4) than the surface of the first insulating layer 21. When the outer layer portion of the temporary support substrate 100 is removed by over-etching in the process of forming the through-hole 90 illustrated in FIG. 3, the lower end of the first contact electrode 91 may be located lower than the surface of the first insulating layer 21 (may protrude from the surface).

After the temporary support substrate 100 is removed, the insulating member 20 is bonded to the exposed surface of the first insulating layer 21 to obtain the semiconductor device illustrated in FIG. 1. The insulating member 20 is, for example, alumina, a ceramic material such as a silicon nitride, or a polymer.

Characteristic effects of the first embodiment are described now.

In the first embodiment, the temporary support substrate 100 (FIG. 4) formed from silicon is removed and the insulating member 20 (FIG. 1) is bonded alternatively. Thus, decrease in high-frequency characteristics caused by the resistance component or the capacitance component attributable to the temporary support substrate 100 is reduced.

The electroconductive member 92 (FIG. 3) in the through-hole 90 is formed from the same material as the conductor films 31B of the second contact electrodes 31. The conductor films 31B are formed from a material that has a preferable ohmic contact with, for example, a Ni silicide or a Co silicide on the surfaces of the source areas 23S and the drain areas 23D. The conductor films 31B of the second contact electrodes 31 are formed from, for example, Ti or TiN. The main portions 31A of the second contact electrodes 31 are formed from a different electroconductive material from the conductor films 31B, for example, W or a W compound.

A known material that has a preferable ohmic contact with, for example, a Ni silicide or a Co silicide on the surfaces of the source areas 23S and the drain areas 23D does not have enough etching resistance against an acid or alkaline etchant. Thus, preventing etching of the electroconductive member 92 in the through-hole 90 during removal of the temporary support substrate 100 is unlikely to succeed. Thus, the electroconductive member 92 is also removed during the etching process of the temporary support substrate 100 (FIG. 5).

In the first embodiment, an optimum material for the lower layer 41B of the first wiring 41 is used to prevent entry of the etchant, while arrival of the etchant at the bottom surface of the first wiring 41 is allowed. For example, a material such as Ta, W, a Ta compound, or a W compound used for the lower layer 41B of the first wiring 41 has higher etching resistance against an acid or alkaline etchant, compared to a material such as Ti or TiN used for the electroconductive member 92. When the etchant enters through the interstice 95 (FIG. 5), and arrives at the first wiring 41, the lower layer 41B functions as a barrier layer to block further entry of the etchant. This structure reduces a failure such as etching of, for example, the first wiring 41.

The second wirings 42 are in contact with the second contact electrodes formed from metal without being in contact with a silicide on the surfaces of the source areas 23S and the drain areas 23D. Thus, the lower layers 42B of the second wirings 42 formed from the same material as the lower layers 41B of the first wirings 41 can obtain a preferable ohmic contact with the second wirings 42 and the second contact electrodes 31.

The lower layer 41B of the first wiring 41 is electroconductive. Thus, during plasma treatment in the wafer process, electric charges accumulated in, for example, the multilayer wiring layer are discharged to the temporary support substrate 100 (FIG. 4) through the first contact electrode 91. This structure thus reduces a breakdown of wirings or the transistors 23 attributable to charging up during plasma treatment.

A modification example of the first embodiment is described now.

In the first embodiment, the electroconductive member 92 (FIG. 4) that covers the side surface and the bottom surface of the first contact electrode 91 during the manufacturing process, and the conductor films 31B of the second contact electrodes 31 are formed from Ti or TiN, and the lower layer 41B of the first wiring 41 is formed from Ta, W, a Ta compound, or a W compound, but they may be formed from other materials. However, preferably, the lower layer 41B of the first wiring 41 is formed from a material having high etching resistance against an acid or alkaline etchant. For example, a material having higher etching resistance against an acid or alkaline etchant than the etching resistance of the conductor films 31B of the second contact electrodes 31 is preferably used as a material of the lower layer 41B of the first wiring 41.

In the first embodiment, etching of the temporary support substrate 100 (FIG. 4) is wet etching using an acid or alkaline etchant. Alternatively, the etching may be dry etching. In this case, a material with higher etching resistance against a dry etching atmosphere than the etching resistance of the conductor films 31B of the second contact electrodes 31 is preferably used as the material of the lower layer 41B of the first wiring 41. Alternatively, the temporary support substrate 100 may undergo polishing halfway by chemical mechanical polishing (CMP), and then undergo wet etching or dry etching.

In the first embodiment, the interstice 95 between the side surface of the through-hole 90 and the first contact electrode 91 is formed as a hollow, but may be partially filled with an adhesive that joins the insulating member 20 and the first insulating layer 21 to each other. An adhesive entering a part of the interstice 95 has effects of increasing the adhesive area, and improving the adhesion of the insulating member 20 to the first insulating layer 21.

In the first embodiment, the lower layer 41B of the first wiring 41 is located to cover the through-hole 90 in a plan view, but a part of the outer edge of the through-hole 90 may overlap the lower layer 41B in a plan view. In other words, a part of the outer edge of the through-hole 90 may pass through the lower layer 41B in a plan view. This structure can reduce entry of an etchant from the outer edge of the through-hole 90 overlapping the lower layer 41B.

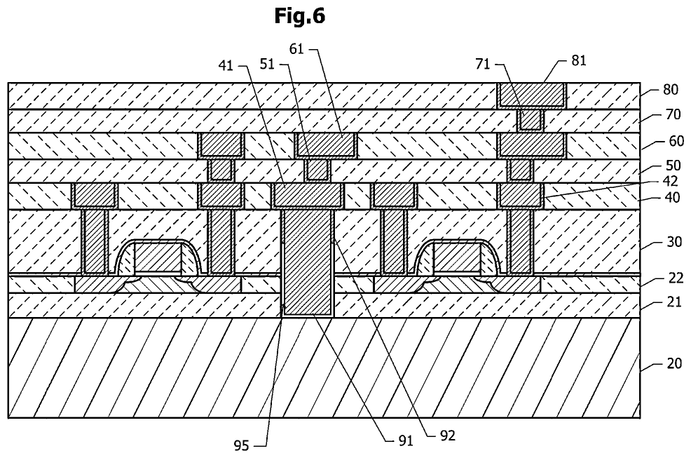

Another modification example of the first embodiment is described with reference to FIG. 6. FIG. 6 is a cross-sectional view of a semiconductor device according to a modification example of the first embodiment. In the first embodiment, in the process of removing the temporary support substrate 100 (FIG. 4) by etching (FIG. 5), the entire electroconductive member 92 (FIG. 4) around the first contact electrode 91 is also removed. In contrast, in the present modification example, the electroconductive member 92 remains in a part of the interstice 95. A part of the electroconductive member 92 can be formed by controlling the duration of the process of etching the temporary support substrate 100. The remaining electroconductive member 92 is in contact with the first wiring 41. In this manner, the electroconductive member 92 does not necessarily have to be entirely etched. Leaving a part of the electroconductive member 92 unremoved has an effect of stabilizing the position of the first contact electrode 91 in the through-hole 90.

### Second Embodiment

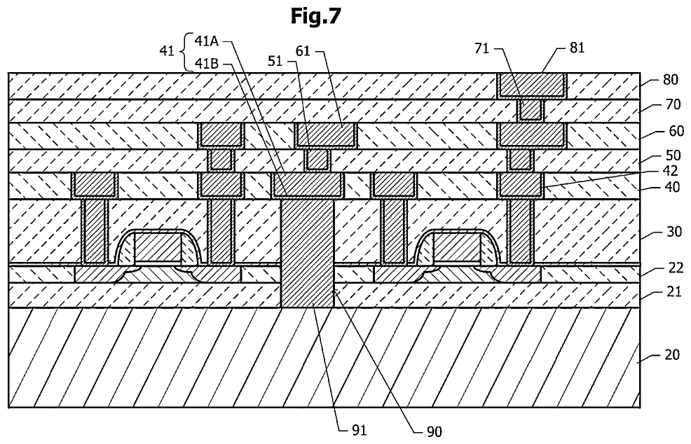

With reference to FIG. 7, a semiconductor device according to a second embodiment is described now. Components the same as those of the semiconductor device according to the first embodiment described with reference to FIG. 1 to FIG. 5 are not described below.

FIG. 7 is a cross-sectional view of the semiconductor device according to a second embodiment. In the first embodiment (FIG. 1), the interstice 95 is formed between the side surface of the through-hole 90 and the first contact electrode 91. In contrast, in the second embodiment, the first contact electrode 91 is in close contact with the side surface of the through-hole 90. The first contact electrode 91 is formed from an electroconductive material, such as W or WN, having high etching resistance against an acid or alkaline etchant for etching the temporary support substrate 100 (FIG. 4).

A method for forming the first contact electrode 91 of the semiconductor device according to the second embodiment is described now. In the first embodiment, in the process illustrated in FIG. 3, the electroconductive member 92 and the first contact electrode 91 in the through-hole 90 are formed, and simultaneously, the main portion 31A and the conductor film 31B of each second contact electrode 31 in the corresponding through-hole 33 are formed. In contrast, in the second embodiment, the process of forming the through-holes 33 and the second contact electrodes 31 and the process of forming the through-hole 90 and the first contact electrode 91 are separately performed. After the through-hole 90 is formed, the first contact electrode 91 is buried in the through-hole 90 without depositing the electroconductive member 92.

Effects of the second embodiment are described now.

In the second embodiment, a material to be etched by an acid or alkaline etchant is not disposed in the through-hole 90. Thus, an etchant is less likely to enter the through-hole 90. However, when the adhesion between the first contact electrode 91 and the first insulating layer 21 is insufficient, the etchant may enter the interface between the first contact electrode 91 and the first insulating layer 21, the element forming layer 22, and the second insulating layer 30, and may arrive at the first wiring 41. As in the case of the first embodiment, also in the second embodiment, the first wiring 41 includes the lower layer 41B formed from a material having high etching resistance against an acid or alkaline etchant. Thus, the second embodiment can reduce an occurrence of a failure attributable to entry of an etchant.

### Third Embodiment

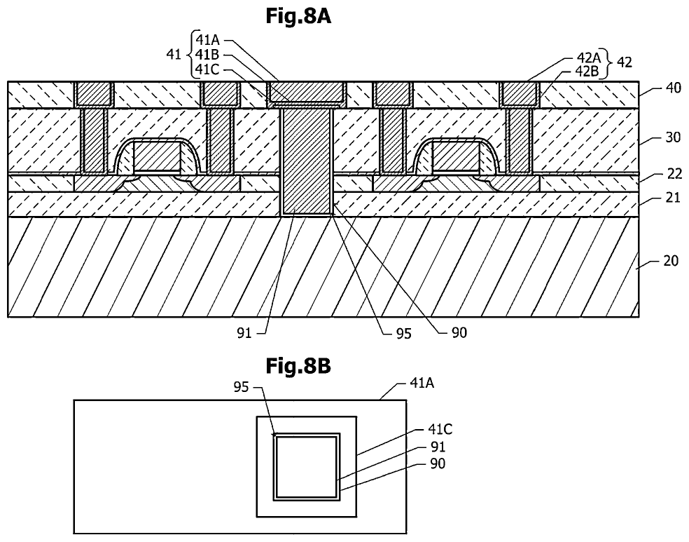

With reference to FIG. 8A and FIG. 8B, a semiconductor device according to a third embodiment is described now. Components the same as those of the semiconductor device according to the first embodiment described with reference to FIG. 1 to FIG. 5 are not described below.

FIG. 8A is a cross-sectional view of a semiconductor device according to a third embodiment, illustrating a portion from the insulating member 20 to the third insulating layer 40, and FIG. 8B is a schematic diagram of a positional relationship between the through-hole 90, the first contact electrode 91, and the first wiring 41 in a plan view. In the third embodiment, the first wiring 41 further includes a lower layer 41C under the lower layer 41B. In a plan view, the lower layer 41C is greater than the through-hole 90, and covers the through-hole 90. The interstice 95 is formed between the side surface of the through-hole 90 and the first contact electrode 91. As in the case of the lower layer 41B (FIG. 1) of the semiconductor device according to the first embodiment, the lower layer 41C of the first wiring 41 has high etching resistance against an acid or alkaline etchant. In FIG. 8B, the through-hole 90 and the first contact electrode 91 are quadrangular in a plan view, but they may be, for example, rounded quadrangular, elliptical, or circular.

A method for manufacturing a semiconductor device according to a third embodiment is described now. Before the third insulating layer 40 is deposited, the lower layer 41C of the first wiring 41 is formed. The third insulating layer 40 is deposited on the second insulating layer 30 and the lower layer 41C, the wiring trenches are formed, and the first wiring 41 and the second wirings 42 are formed.

Effects of the third embodiment are described now.

In the third embodiment, the lower layer 41C of the first wiring 41, located at the lowest in the first wiring 41, functions as a barrier layer to block entry of the etchant during etching of the temporary support substrate 100 (FIG. 4). Thus, as in the case of the first embodiment, the third embodiment can reduce an occurrence of a failure attributable to entry of an etchant.

In the first embodiment, to cause the lower layer 41B of the first wiring 41 to function as a barrier layer, the lower layer 41B is formed from an electroconductive material having high etching resistance against an acid or alkaline etchant. In the third embodiment, the second lower layer 41B has no need of functioning as a barrier layer, and the material of the lower layer 41B is selectable more freely. The lower layers 42B of the second wirings 42 are formed from the same material as the lower layer 41B of the first wiring 41, and thus, the material of the second wirings 42 is also selectable more freely. For example, optimum materials for the materials of the lower layers 41B and 42B may be selected in consideration of, for example, electric characteristics, or adhesion to the third insulating layer 40.

In the third embodiment, the lowest lower layer 41C functions as a barrier layer. Thus, the main portion 41A and the lower layer 41B of the first wiring 41 may have any structure as long as they are electrically connected to the lower layer 41C. Thus, the main portion 41A and the lower layer 41B of the first wiring 41 do not have to cover the through-hole 90 in a plan view. Thus, the third embodiment has an effect of improving the degree of freedom in arrangement of the first wiring 41.

A modification example of the third embodiment is described now.

In the third embodiment, the lower layer 41C functions as a barrier layer. This structure has no need of providing the lower layer 41B adhering to the side surface and the bottom surface of the main portion 41A of the first wiring 41.

### Fourth Embodiment

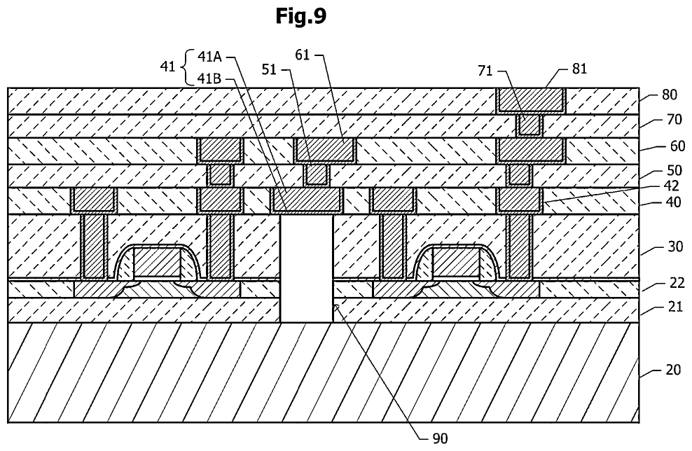

With reference to FIG. 9, a semiconductor device according to a fourth embodiment is described now. Components the same as those of the semiconductor device according to the first embodiment described with reference to FIG. 1 to FIG. 5 are not described below.

FIG. 9 is a cross-sectional view of a semiconductor device according to a fourth embodiment. In the first embodiment (FIG. 1), the first contact electrode 91 is disposed in the through-hole 90. In contrast, in the fourth embodiment, the through-hole 90 is hollow.

A method for manufacturing the semiconductor device according to the fourth embodiment is described now. In the first embodiment, the first contact electrode 91 (FIG. 1) is formed from a material having high etching resistance against an acid or alkaline etchant. In the fourth embodiment, the first contact electrode 91 is formed from an electroconductive material easily etchable by an acid or alkaline etchant, such as polysilicon. Thus, in the process (FIG. 5) of etching the temporary support substrate 100 (FIG. 4), the first contact electrode 91 is also etched to form a hollow in the through-hole 90.

Effects of the fourth embodiment are described now.

As in the case of the first embodiment, also in the fourth embodiment, the lower layer 41B of the first wiring 41 functions as a barrier layer to block entry of the etchant. Thus, the fourth embodiment can reduce an occurrence of a failure attributable to entry of an etchant. When the first contact electrode 91 with electroconductivity, irrelevant to the operations of the transistors 23, are located near the transistors 23, high-frequency characteristics of the transistors 23 may be lowered with the effect of the parasitic capacitance between the transistors 23 and the first contact electrode 91. In the fourth embodiment, no electroconductive material is disposed in the through-hole 90. Thus, decrease of the high-frequency characteristics of the transistors 23 attributable to the electroconductive material in the through-hole 90 may be lowered.

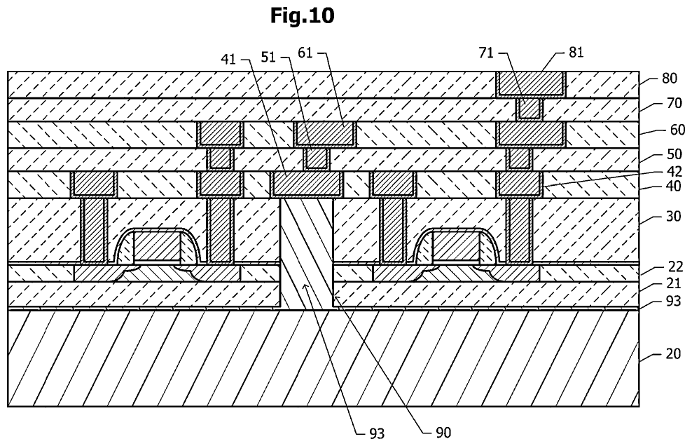

With reference to FIG. 10, a semiconductor device according to a modification example of the fourth embodiment is described now. FIG. 10 is a cross-sectional view of a semiconductor device according to a modification example of the fourth embodiment. In the fourth embodiment (FIG. 9), the through-hole 90 is hollow. In contrast, in the present modification example, the through-hole 90 is filled with a resin member 93 that functions as an adhesive that is bonded to the insulating member 20 and the first insulating layer 21. In the present modification example, the bonding area between the first insulating layer 21 and the resin member 93 is increased. Thus, the present modification example has an effect of improving the adhesive strength of the insulating member 20 to the first insulating layer 21.

### Fifth Embodiment

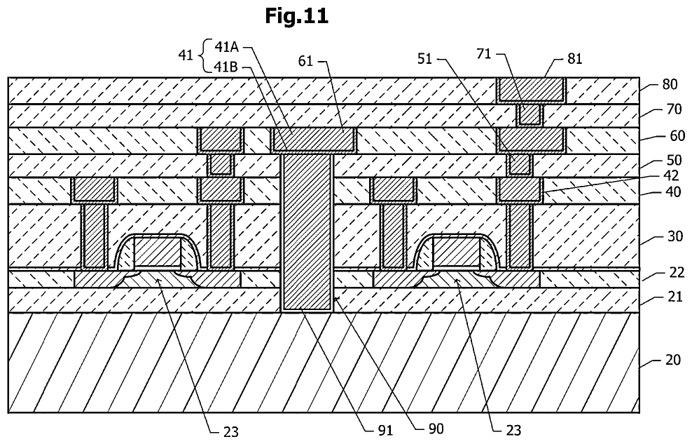

With reference to FIG. 11, a semiconductor device according to a fifth embodiment is described now. Components the same as those of the semiconductor device according to the first embodiment described with reference to FIG. 1 to FIG. 5 are not described below.

FIG. 11 is a cross-sectional view of a semiconductor device according to a fifth embodiment. In the first embodiment (FIG. 1), the first wiring 41 connected to the first contact electrode 91 is disposed on the first wiring layer on the second insulating layer 30. In contrast, in the fifth embodiment, the first wiring 41 connected to the first contact electrode 91 is disposed on the second wiring layer on the fourth insulating layer 50. As in the first wiring 41 (FIG. 1) of the semiconductor device according to the first embodiment, the first wiring 41 includes the main portion 41A and the lower layer 41B. The lower layer 41B has high etching resistance against an acid or alkaline etchant.

The through-hole 90 extends through the fourth insulating layer 50, the third insulating layer 40, the second insulating layer 30, the element isolation area of the element forming layer 22, and the first insulating layer 21 to the insulating member 20. As in the case of the first embodiment, the first contact electrode 91 is disposed in the through-hole 90.

A method for manufacturing a semiconductor device according to a fifth embodiment is described now. In the first embodiment (FIG. 3), the through-hole 90 is formed in the process of forming the through-holes 33 for the second contact electrodes 31. In contrast, in the fifth embodiment, the through-hole 90 is formed in the process of forming via holes for via conductors 51 in the fourth insulating layer 50. The through-hole 90 may be formed separately from a process of forming via holes.

Effects of the fifth embodiment are described now. As in the case of the first embodiment, also in the fifth embodiment, the lower layer 41B of the first wiring 41 functions as a barrier layer. The fifth embodiment can thus reduce an occurrence of a failure attributable to entry of an etchant. When the first wiring layer does not have enough space for receiving the first wiring 41, the structure of the fifth embodiment may be employed.

### Sixth Embodiment

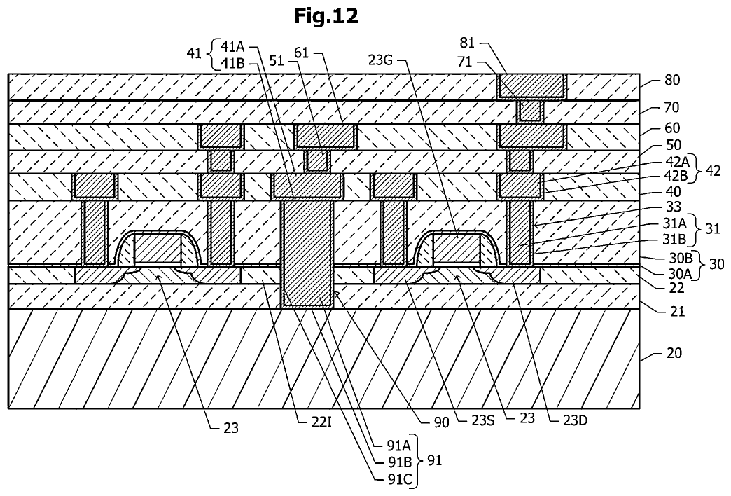

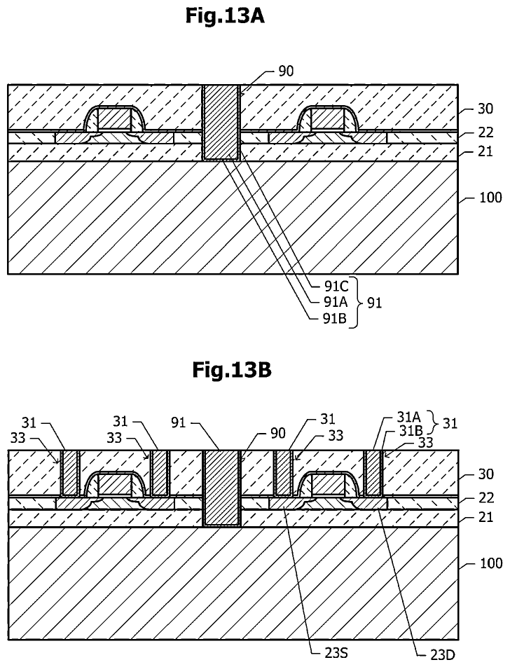

With reference to FIG. 12, FIG. 13A, and FIG. 13B, a semiconductor device according to a sixth embodiment is described now. Components the same as those of the semiconductor device according to the first embodiment described with reference to FIG. 1 to FIG. 5 are not described below.

FIG. 12 is a cross-sectional view of a semiconductor device according to a sixth embodiment. In the first embodiment (FIG. 1), the interstice 95 is formed between the side surface of the through-hole 90 and the first contact electrode 91 disposed in the through-hole 90, and between the first contact electrode 91 and the insulating member 20. In contrast, in the sixth embodiment, the first contact electrode 91 is in contact with the side surface of the through-hole 90 and the insulating member 20.

The first contact electrode 91 extends through the second insulating layer 30, the element isolation area 221 of the element forming layer 22, and the first insulating layer 21 from the lower surface of the first wiring 41 to the insulating member 20. The first contact electrode 91 is electrically connected to the first wiring 41.

The first contact electrode 91 includes a first main portion 91A with electroconductivity, a bottom portion 91B disposed nearer the insulating member 20 than the first main portion 91A, and a side portion 91C disposed on the side surface of the first main portion 91A. The bottom portion 91B and the side portion 91C are formed from a different material from the conductor films 31B of the second contact electrodes 31. The bottom portion 91B and the side portion 91C are formed from a material less easily etchable by an acid or alkaline etchant than the material of the conductor films 31B. For example, the bottom portion 91B and the side portion 91C are formed from Ta, W, a Ta compound, or a W compound. Ta is less easily etchable by an acid or alkaline etchant than W. Thus, W or a W compound is preferably used as the material of the first main portion 91A, and Ta or a Ta compound (such as TaN) is preferably used as the material of the bottom portion 91B and the side portion 91C. A film formed from the same material as the conductor films 31B may be disposed between the first main portion 91A and the bottom portion 91B, and between the first main portion 91A and the side portion 91C.

With reference to FIG. 13A and FIG. 13B, a method for manufacturing a semiconductor device according to a sixth embodiment is described. FIG. 13A and FIG. 13B are cross-sectional views of the semiconductor device according to the sixth embodiment during the manufacturing process. In the first embodiment (FIG. 3), the first contact electrode 91 and the second contact electrodes 31 are simultaneously formed in the same process, but they are separately formed in different processes in the sixth embodiment.

As illustrated in FIG. 13A, the through-hole 90 extending from the upper surface of the second insulating layer 30 to the temporary support substrate 100 is formed. The through-hole 90 is filled with the first contact electrode 91. The first contact electrode 91 may be formed by, for example, damascening. The bottom portion 91B and the side portion 91C may be deposited by, for example, sputtering or chemical vapor deposition (CVD). The first main portion 91A may be deposited by, for example, CVD.

As illustrated in FIG. 13B, the multiple through-holes 33 extending from the upper surface of the second insulating layer 30 to the drain areas 23D and the source areas 23S of the transistors 23 are then formed. The multiple through-holes 33 are filled with the second contact electrodes 31. The second contact electrodes 31 may be formed by, for example, damascening. The main portion 31A and the conductor film 31B of each second contact electrode 31 are formed from the same material as the main portion 31A and the conductor film 31B of each second contact electrode 31 according to the first embodiment (FIG. 1).

Thereafter, as in the process described with reference to FIG. 4 and FIG. 5 in the first embodiment, the multilayer wiring layer is formed, the temporary support substrate 100 is removed, and the insulating member 20 (FIG. 12) is bonded.

Effects of the sixth embodiment are described now.

As in the case of the first embodiment, also in the sixth embodiment, the temporary support substrate 100 (FIG. 4) with electroconductivity is removed, and, instead, the insulating member 20 is bonded. Thus, the sixth embodiment can improve the high-frequency characteristics.

In the sixth embodiment, the bottom portion 91B of the first contact electrode 91 functions as an etching barrier during etching of the temporary support substrate 100 (FIG. 4) with an acid or alkaline etchant. Thus, the sixth embodiment can reduce an occurrence of a failure attributable to entry of an etchant. To enhance the effects of preventing entry of an etchant, preferably, the outer peripheral portion of the bottom portion 91B of the first contact electrode 91 is in contact with the first insulating layer 21 without leaving a gap therebetween.

A modification example of the sixth embodiment is described now.

In the sixth embodiment, the side portion 91C is disposed on the side surface of the first main portion 91A of the first contact electrode 91. Instead, the side portion 91C may be omitted, and the first main portion 91A may be in contact with the side surface of the through-hole 90. This structure may be formed by highly anisotropic sputtering, such as long slow sputtering, or collimate sputtering during deposition of the bottom portion 91B. Also in this structure, the bottom portion 91B functions as an etching barrier, and the sixth embodiment can thus reduce an occurrence of a failure attributable to entry of an etchant.

### Seventh Embodiment

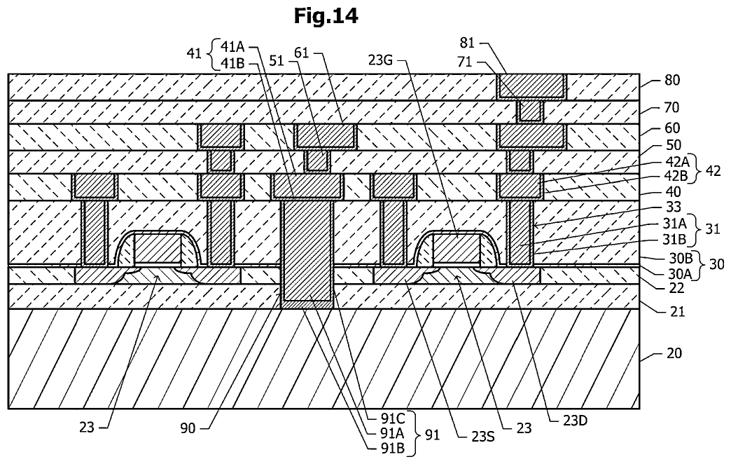

With reference to FIG. 14, a semiconductor device according to a seventh embodiment is described now. Components the same as those of the semiconductor device according to the sixth embodiment described with reference to FIG. 12, FIG. 13A, and FIG. 13B are not described below.

FIG. 14 is a cross-sectional view of a semiconductor device according to a seventh embodiment. As in the sixth embodiment, also in the seventh embodiment, the first contact electrode 91 includes the first main portion 91A, the bottom portion 91B, and the side portion 91C. In the semiconductor device according to the seventh embodiment, the thickness of the bottom portion 91B is greater than the thickness of the side portion 91C. In the structure where the bottom portion 91B is thicker than the side portion 91C, the bottom portion 91B and the side portion 91C may be formed by, for example, sputtering with directivity.

Effects of the seventh embodiment are described now.

As in the case of the first embodiment, also in the seventh embodiment, the temporary support substrate 100 (FIG. 4) with electroconductivity is removed, and, instead, the insulating member 20 is bonded. Thus, the seventh embodiment can improve the high-frequency characteristics. In addition, in the seventh embodiment, the bottom portion 91B of the first contact electrode 91 is thicker than the side portion 91C, and thus has an enhanced function as an etching barrier during removal of the temporary support substrate 100 (FIG. 4). The side portion 91C is relatively thin, and thus the first contact electrode 91 has sufficient electroconductivity.

### Eighth Embodiment

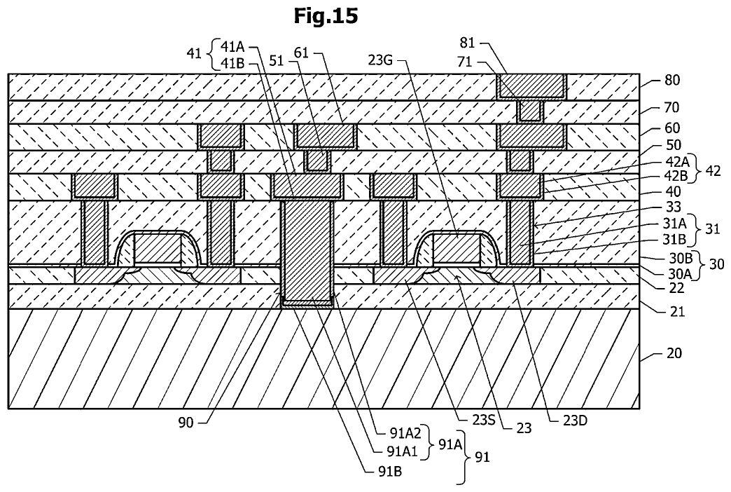

With reference to FIG. 15, a semiconductor device according to an eighth embodiment is described now. Components the same as those of the semiconductor device according to the sixth embodiment described with reference to FIG. 12, FIG. 13A, and FIG. 13B are not described below.

FIG. 15 is a cross-sectional view of a semiconductor device according to an eighth embodiment. In the semiconductor device according to the eighth embodiment, the first contact electrode 91 has a different structure from the first contact electrode 91 of the semiconductor device according to the sixth embodiment. The first contact electrode 91 of the semiconductor device according to the eighth embodiment includes a first main portion 91A and a bottom portion 91B. The bottom portion 91B is disposed between the first main portion 91A and the insulating member 20.

The first main portion 91A includes a first main pillar 91A1 and a main pillar film 91A2. The main pillar film 91A2 covers the upper surface of the bottom portion 91B and the side surface of the through-hole 90. The remaining space of the through-hole 90 is filled with the first main pillar 91A1. The material of the main pillar film 91A2 is the same as the material of the conductor films 31B of the second contact electrodes 31, and the material of the first main pillar 91A1 is the same as the material of the main portions 31A of the second contact electrodes 31. The material of the bottom portion 91B is the same as the material of the bottom portion 91B of the first contact electrode 91 of the semiconductor device according to the sixth embodiment.

The bottom portion 91B may be formed by, for example, sputtering with high directivity. While the bottom portion 91B is being formed, the material of the bottom portion 91B may be deposited on the side surface of the through-hole 90. In this case, the main pillar film 91A2 may be deposited on the same material as the material of the bottom portion 91B deposited on the side surface of the through-hole 90. The main pillar film 91A2 and the first main pillar 91A1 are formed in the same process as damascening in which the conductor films 31B and the main portions 31A of the second contact electrodes 31 are formed.

Effects of the eighth embodiment are described now.

Also in the eighth embodiment, as in the case of the first embodiment, the temporary support substrate 100 (FIG. 4) with electroconductivity is removed, and, instead, the insulating member 20 is bonded. Thus, the eighth embodiment can improve the high-frequency characteristics. Also in the eighth embodiment, as in the sixth embodiment, the bottom portion 91B of the first contact electrode 91 functions as an etching barrier during etching of the temporary support substrate 100 (FIG. 4). Thus, the eighth embodiment can reduce an occurrence of a failure attributable to entry of an etchant. In the eighth embodiment, the first main pillar 91A1 and the main pillar film 91A2 of the first contact electrode 91, and the main portions 31A and the conductor films 31B of the second contact electrodes 31 can be formed by the same damascening. Thus, the manufacturing process can be simplified.

The above embodiments are mere examples, and components from different embodiments may naturally and partially be replaced from each other or combined with each other. Similar operations and effects between similar components from multiple embodiments are not redundantly described for each embodiment. The present disclosure is not limited to the above embodiments. For example, it is apparent for persons having ordinary skill in the art that the embodiments may be changed, modified, or combined in various manners.

What is claimed is:

1. A semiconductor device, comprising:
an insulating member;
a first insulating layer including a silicon oxide and being on a surface of the insulating member;
a transistor over a part of an area of the first insulating layer;
a second insulating layer covering the first insulating layer and the transistor; and
a first wiring on the second insulating layer,
wherein
a through-hole extends through the second insulating layer and the first insulating layer from a lower surface of the first wiring to the insulating member, and at least a part of an outer edge of the through-hole overlaps the first wiring in a plan view, and
the first wiring includes a lower layer that is in contact with the second insulating layer, and the lower layer includes: Ta, W, a Ta compound, or a W compound.

2. The semiconductor device according to claim 1, further comprising:
a first contact electrode that is in the through-hole, includes W or a W compound, and is in contact with the first wiring.

3. The semiconductor device according to claim 2, further comprising:
a second contact electrode that extends through the second insulating layer and that is connected to the transistor,
wherein the second contact electrode includes a main portion with electroconductivity and a conductor film covering a side surface and a bottom surface of the main portion, and a material of the conductor film is different from a material of the first contact electrode.

4. The semiconductor device according to claim 3, wherein
the conductor film includes Ti or a Ti compound.

5. The semiconductor device according to claim 3, wherein
the first contact electrode is spaced a distance apart from a side surface of the through-hole, and an electroconductive member including a material the same as the material of the conductor film is in at least a part of a space between the first contact electrode and the side surface of the through-hole.

6. The semiconductor device according to claim 1, wherein
the through-hole is hollow.

7. The semiconductor device according to claim 1, further comprising:
a resin member in the through-hole.

8. The semiconductor device according to claim 1, wherein
the insulating member includes an insulating polymer.

9. The semiconductor device according to claim 1, wherein
at least a part of the through-hole overlaps the lower layer in a plan view.

10. The semiconductor device according to claim 4, wherein
the first contact electrode is spaced a distance apart from a side surface of the through-hole, and an electroconductive member including a material the same as the material of the conductor film is in at least a part of a space between the first contact electrode and the side surface of the through-hole.

11. The semiconductor device according to claim 2, wherein
the insulating member includes an insulating polymer.

12. A semiconductor device, comprising:
an insulating member;
a first insulating layer including a silicon oxide and being on a surface of the insulating member;
a transistor over a part of an area of the first insulating layer;
a second insulating layer covering the first insulating layer and the transistor;
a first wiring on the second insulating layer; and
a first contact electrode extending through the second insulating layer and the first insulating layer from a lower surface of the first wiring to the insulating member,
wherein the first contact electrode includes a first main portion with electroconductivity and a bottom portion nearer the insulating member than the first main portion, and the bottom portion includes: Ta, W, a Ta compound, or a W compound.

13. The semiconductor device according to claim 12, wherein
the first main portion includes W or a W compound, and the bottom portion includes Ta or a Ta compound.

14. The semiconductor device according to claim 12, further comprising:
a second contact electrode extending through the second insulating layer and connected to the transistor,
wherein the second contact electrode includes a second main portion with electroconductivity and a conductor film covering a side surface and a bottom surface of the second main portion, and a material of the conductor film is different from a material of the bottom portion.

15. The semiconductor device according to claim 14,
wherein the conductor film includes Ti or a Ti compound.

16. The semiconductor device according to claim 12, wherein
the first contact electrode further includes a side portion that is in contact with a side surface of the first main portion, and
wherein the side portion includes: Ta, W, a Ta compound, or a W compound.

17. The semiconductor device according to claim 16, wherein
a thickness of the bottom portion is greater than a thickness of the side portion.

18. The semiconductor device according to claim 14, wherein
the first main portion includes a first main pillar and a main pillar film covering a side surface and a bottom surface of the first main pillar, and
wherein a material of the main pillar film is the same as a material of the conductor film of the second contact electrode.

19. The semiconductor device according to claim 13, further comprising:
a second contact electrode extending through the second insulating layer and connected to the transistor,
wherein the second contact electrode includes a second main portion with electroconductivity and a conductor film covering a side surface and a bottom surface of the second main portion, and a material of the conductor film is different from a material of the bottom portion.

20. The semiconductor device according to claim 13, wherein
the first contact electrode further includes a side portion that is in contact with a side surface of the first main portion, and
wherein the side portion includes: Ta, W, a Ta compound, or a W compound.
